(19) United States
(12) Patent Application Publication
(10) Pub. No.: US 2026/0107575 A1
(43) Pub. Date: Apr. 16, 2026

(54) SEMICONDUCTOR DEVICE AND METHOD FOR FORMING THE SAME

(71) Applicant: Hon Young Semiconductor Corporation, Hsinchu City (TW)

(72) Inventor: Chao-Yi CHANG, Hsinchu City (TW)

(21) Appl. No.: 18/988,930

(22) Filed: Dec. 20, 2024

(30) Foreign Application Priority Data
Oct. 11, 2024 (TW) 113138612

(51) Int. Cl. H10D 86/40; H10D 86/01

(52) U.S. Cl. CPC H10D 86/441; H10D 86/0221

(57) ABSTRACT

A semiconductor device includes a substrate, an epitaxial layer, a first well, a dielectric layer, a gate electrode layer, and a source pad. The substrate includes an array region and a peripheral region. The epitaxial layer is over the substrate. The first well is in the epitaxial layer. The dielectric layer is over the epitaxial layer and over the array region and the peripheral region. The gate electrode layer is over the dielectric layer and over the array region and the peripheral region. The gate electrode layer has at least one opening over the peripheral region. The source pad is over the gate electrode layer and extends from over the array region to over the peripheral region. The source pad has at least one first extending portion extending through the at least one opening of the gate electrode layer downward to the first well.

### CROSS-REFERENCE TO RELATED APPLICATION

This application claims priority to Taiwan Application Serial Number 113138612, filed Oct. 11, 2024, which is herein incorporated by reference in its entirety.

### BACKGROUND

### Field of Disclosure

The present disclosure relates to a semiconductor device and a method for forming the same.

### Description of Related Art

As semiconductor manufacturing technology matures, the feature size of semiconductor devices shrinks, and the demand for switching speed gradually increases. One of the main factors that affects the switching speed and device stability is the parasitic capacitance of the gate, which may lead to charge accumulation. Accordingly, how to provide a semiconductor device and a method for forming a semiconductor device that can reduce gate-related parasitic capacitances becomes an important issue to be solved by those in the industry.

### SUMMARY

An aspect of the disclosure is to provide a semiconductor device and a method for forming a semiconductor device that may efficiently solve the aforementioned problems.

According to an embodiment of the disclosure, a semiconductor device includes a substrate, an epitaxial layer, a first well, a dielectric layer, a gate electrode layer, and a source pad. The substrate includes an array region and a peripheral region that are adjacent to each other. The epitaxial layer is over the substrate. The first well is in the epitaxial layer. The dielectric layer is over the epitaxial layer and over the array region and the peripheral region. The gate electrode layer is over the dielectric layer and over the array region and the peripheral region. The gate electrode layer has at least one opening over the peripheral region. The source pad is over the gate electrode layer and extends from over the array region to over the peripheral region. The source pad has at least one first extending portion extending through the at least one opening of the gate electrode layer downward to the first well.

According to an embodiment of the disclosure, a method for forming a semiconductor device includes forming an epitaxial layer over a substrate. The substrate includes an array region and a peripheral region that are adjacent to each other. The method further includes forming a first well in the epitaxial layer and over the peripheral region. The method further includes forming a first dielectric layer over the epitaxial layer and over the array region and the peripheral region. The method further includes forming a gate electrode layer over the first dielectric layer and over the array region and the peripheral region. The method further includes forming a hole over the peripheral region. The hole passes through the gate electrode layer and the first dielectric layer and exposes the first well. The method further includes forming a source pad over the gate electrode layer and in contact with the first well through the hole.

Accordingly, in the semiconductor device and the method for forming the semiconductor device of some embodiments of the present disclosure, by forming multiple openings in the gate electrode layer over the peripheral region, the overlapping area between the gate electrode layer and the underlying dielectric layer can be reduced. In this way, the parasitic capacitance of the resultant device can be reduced, thereby improving its switching characteristics, enhancing forward conduction capability, and increasing switching stability. In addition, extending the source pad into the aforementioned openings can increase the source contact area and reduce the source-drain voltage (V_{sd}).

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 and FIG. 2 are partial cross-sectional views of a semiconductor device according to some embodiments of the present disclosure;

FIG. 3 is a top view of a semiconductor device according to some embodiments of the present disclosure;

FIG. 4 is a partial enlarged view of a semiconductor device in a square 4 of FIG. 3 according to some embodiments of the present disclosure;

FIG. 5 is a top view of a semiconductor device according to some other embodiments of the present disclosure;

FIG. 6 is a partial cross-sectional view of a semiconductor device according to some other embodiments of the present disclosure; and

FIG. 7 is a flow chart of a method for forming a semiconductor device according to some embodiments of the present disclosure.

### DETAILED DESCRIPTION

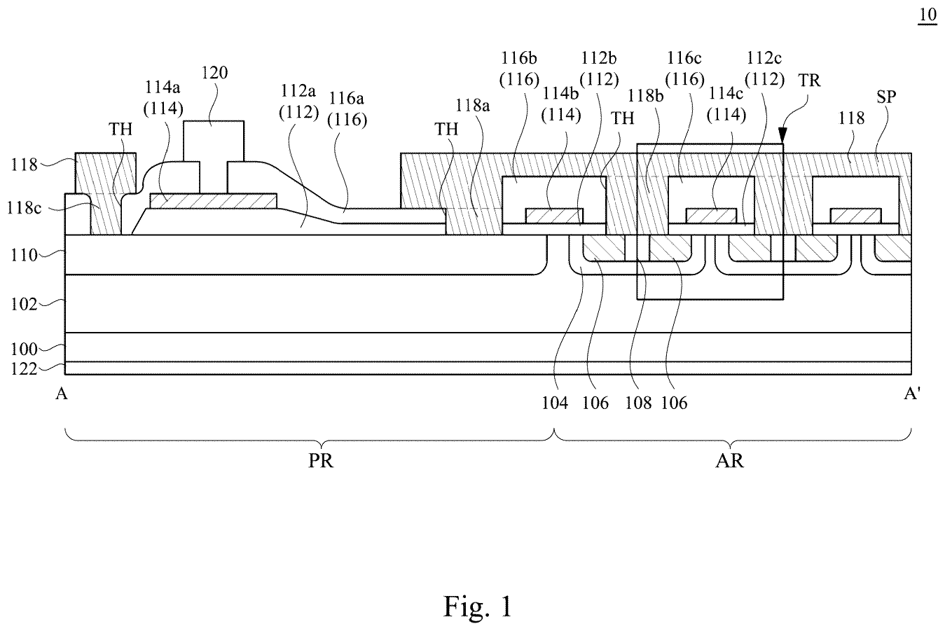

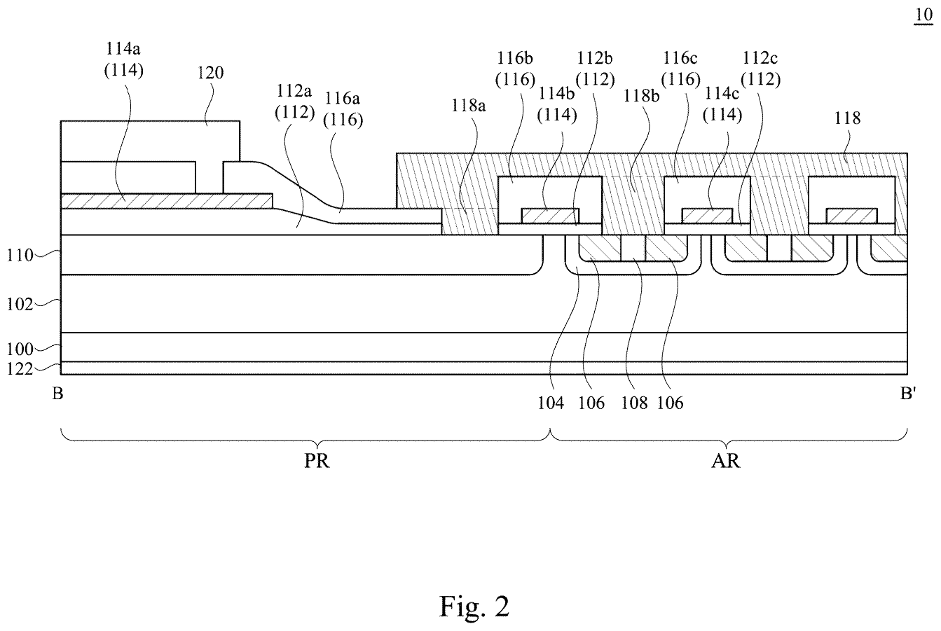

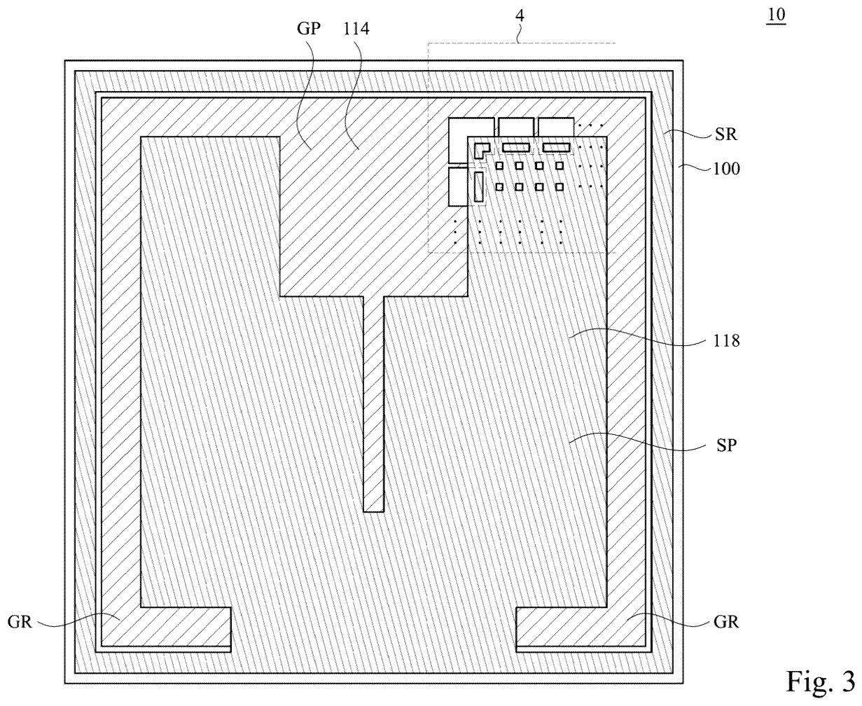

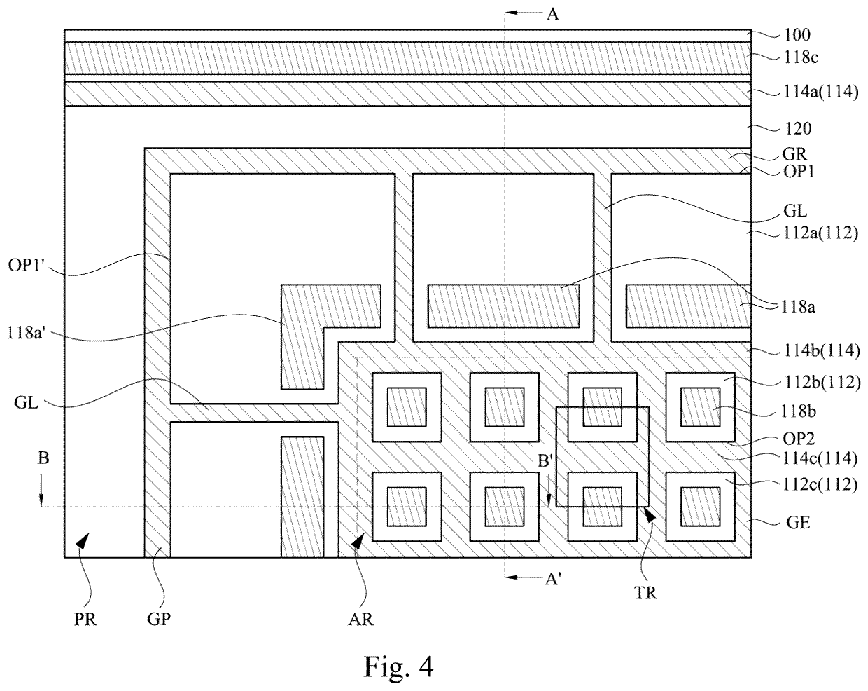

Reference is made to FIG. 1 to FIG. 4. FIG. 1 is a partial cross-sectional view of a semiconductor device 10 according to some embodiments of the present disclosure. FIG. 2 is a partial cross-sectional view of the semiconductor device 10 along another cross-sectional line. FIG. 3 is a top view of the semiconductor device 10. FIG. 4 is a partial enlarged view of the semiconductor device 10 in a square 4 of FIG. 3. In greater detail, FIG. 1 is taken along a line A-A′ in FIG. 4, and FIG. 2 is taken along a line B-B′ in FIG. 4.

Reference is made to FIG. 1 and FIG. 2. The semiconductor device 10 includes a substrate 100, an epitaxial layer 102, a well 104, a source region 106, a body contact region 108, and a well 110. The substrate 100 includes an array region AR and a peripheral region PR that are adjacent to each other. The epitaxial layer 102 is disposed over the substrate 100. The well 104 is disposed in the epitaxial layer 102 and over the array region AR of the substrate 100. The source region 106 and the body contact region 108 are disposed in the well 104 and over the array region AR of the substrate 100. The well 110 is disposed in the epitaxial layer 102 and over the peripheral region PR of the substrate 100. The well 110 and the well 104 may be separated from each other or may be connected. In some embodiments, a width of the well 104 is less than a width of the well 110, as shown in FIG. 1 and FIG. 2.

In some embodiments, the substrate 100, the epitaxial layer 102, and the source region 106 have a first conductivity type. For example, the substrate 100, the epitaxial layer 102, and the source region 106 are n-type semiconductor layers. In some embodiments, the substrate 100, the epitaxial layer 102, and the source region 106 have the same n-type dopants. In some embodiments, a dopant concentration of the source region 106 is greater than a dopant concentration of the epitaxial layer 102.

In some embodiments, the well 104, the body contact region 108, and the well 110 have a second conductivity type that is different from the first conductivity type. For example, the well 104, the body contact region 108, and the well 110 are p-type semiconductor layers. In some embodiments, the well 104, the body contact region 108, and the well 110 have the same p-type dopants. In some embodiments, a dopant concentration of the body contact region 108 is greater than a dopant concentration of the well 104. An overall dopant concentration of the well 110 may be substantially equal to the dopant concentration of the well 104 or the dopant concentration of the body contact region 108 or other dopant concentrations. In other words, the dopant concentration at any location in the well 110 is not limited to any dopant concentration. In some embodiments, the well 110 has substantially no n-type dopants of the source region 106. In other embodiments, the dopant concentration of the n-type dopants of the well 110 is substantially equal to or less than the dopant concentration of the n-type dopants of the source region 106.

As shown in FIG. 1 and FIG. 2, the semiconductor device 10 further includes a first dielectric layer 112, a gate electrode layer 114, and a second dielectric layer 116. The first dielectric layer 112 is disposed over the epitaxial layer 102 and over the array region AR and the peripheral region PR of the substrate 100. To be more specific, a first dielectric layer 112a is disposed over the peripheral region PR. The first dielectric layer 112a may include a dielectric material stack formed by a series of processes and have a thickness variation as shown in FIG. 1 (e.g., the thickness of the first dielectric layer 112a on a side that is close to the array region AR is smaller). A first dielectric layer 112b is disposed over both the array region AR and the peripheral region PR. A first dielectric layer 112c is disposed over the array region AR. A gate electrode layer 114 is disposed over the first dielectric layer 112 and over the array region AR and the peripheral region PR of the substrate 100. In greater detail, a gate electrode layer 114a is disposed over the peripheral region PR. In some embodiments, the gate electrode layer 114a may extend toward the array region AR to over the portion of the first dielectric layer 112a having a smaller thickness, but the present disclosure is not limited thereto. A gate electrode layer 114b is disposed over both the array region AR and the peripheral region PR. A gate electrode layer 114c is disposed over the array region AR. The second dielectric layer 116 covers the gate electrode layer 114 and the first dielectric layer 112. To be more specific, a second dielectric layer 116a covers the gate electrode layer 114a and the first dielectric layer 112a. A second dielectric layer 116b covers the gate electrode layer 114b and the first dielectric layer 112b. A second dielectric layer 116c covers the gate electrode layer 114c and the first dielectric layer 112c. The first dielectric layer 112c, the gate electrode layer 114c, and the second dielectric layer 116c can serve as a gate structure of the transistor TR in the array region AR, in which the first dielectric layer 112c serves as a gate dielectric layer, and the second dielectric layer 116c serves as an interlayer dielectric (ILD). In some embodiments, the first dielectric layer 112 and the second dielectric layer 116 may include a dielectric material, such as silicon dioxide (SiO₂), aluminum oxide (Al₂O₃), or other suitable materials. In some embodiments, the gate electrode layer 114 may include polysilicon, a conductive metal, or other suitable material.

It should be noted that the transistor TR in the array region AR of the semiconductor device in the present disclosure can be any transistor structure and is not limited to the structure disclosed in the drawings.

As shown in FIG. 1 and FIG. 2, the semiconductor device 10 further includes a source pad 118, a gate pad 120, and a drain pad 122. The source pad 118 is disposed over the gate electrode layer 114 and the second dielectric layer 116 and extends from over the array region AR to over the peripheral region PR. The source pad 118 has a pad region SP and multiple extending portions. For example, the pad region SP of the source pad 118 is a horizontal portion disposed over the second dielectric layer 116. The extending portions 118a and the extending portions 118b of the source pad 118 extend downward from the pad region SP through the second dielectric layer 116c, the gate electrode layer 114c, and the first dielectric layer 112c. In some embodiments, the extending portions 118a are over the peripheral region PR and extend to be in contact with the well 110. The extending portions 118a are disposed on a side of the gate electrode layer 114a that is close to the array region AR and between the gate electrode layer 114a and the gate electrode layer 114b. In some embodiments, the extending portions 118b are over the array region AR, extend to be in contact with the source region 106 and the body contact region 108, and are electrically connected to the source region 106. In some embodiments, the source pad 118 further has extending portions 118c. The extending portions 118c are over the peripheral region PR, are disposed on a side of the gate electrode layer 114 (such as the gate electrode layer 114a) that is away from the array region AR, and extend downward from the pad region SP of the source pad 118 through the second dielectric layer 116 to be in contact with the well 110. The gate pad 120 is disposed over the peripheral region PR and in contact with the gate electrode layer 114 (such as the gate electrode layer 114a). The drain pad 122 is disposed on a side of the substrate 100 that is away from the epitaxial layer 102.

Reference is made to FIG. 3. For the sake of clarity, FIG. 3 only illustrates the substrate 100, the gate electrode layer 114, and the source pad 118 of the semiconductor device 10. The gate electrode layer 114 has a pad region GP and a ring-shaped portion GR connected to each other and over the peripheral region PR. The ring-shaped portion GR may also be referred to as a gate bus. The source pad 118 is disposed over the gate electrode layer 114 and has a ring-shaped portion SR. As shown in FIG. 3, the source pad 118 partially covers and surrounds the pad region GP of the gate electrode layer 114 and is partially surrounded by the ring-shaped portion GR. In addition, the ring-shaped portion SR of the source pad 118 completely surrounds the gate electrode layer 114.

Reference is made to FIG. 4. For the sake of clarity, the top view of FIG. 4 omits the second dielectric layer 116 and the pad region SP of the source pad 118 of the semiconductor device 10. As shown in FIG. 4, the gate electrode layer 114 has multiple openings over the peripheral region PR and arranged at intervals along an outer edge of the array region AR. To be more specific, the gate electrode layer 114 has openings OP1 and openings OP1′. The extending portions 118a and the extending portions 118a′ of the source pad 118 respectively extend into the openings OP1 and the openings OP1′. The openings OP1 may have rectangular profiles in the top view. Accordingly, the extending portions 118a formed in the openings OP1 may have rectangular profiles in the top view as well. Since the openings of the gate electrode layer 114 are arranged along the outer edge of the array region AR, the openings OP1′ may have L-shaped profiles in the top view. In accordance, the extending portions 118a′ formed in the openings OP1′ may have L-shaped profiles in the top view as well.

In addition, as shown in FIG. 4, strip-shaped portions between two adjacent ones of the openings OP1 and/or openings OP1′ of the gate electrode layer 114 connect the gate electrode layer 114b and the gate electrode layer 114c in the array region AR to the gate electrode layer 114a in the peripheral region PR. These strip-shaped portions may be referred to as gate lines GL. In greater detail, the gate lines GL connect the gate electrode portions GE (including the gate electrode layer 114b and the gate electrode layer 114c) over the array region AR to the pad region GP and the ring-shaped portion GR (including the gate electrode layer 114a) over the peripheral region PR. Meanwhile, each of the gate lines GL is disposed between two adjacent ones of the extending portions 118a and/or extending portions 118a′. In this way, the number, shape, and size of the openings OP1 and/or openings OP1′ can be adjusted to control the number, shape, and size of the gate lines GL. Thereby, the gate internal resistance of the semiconductor device 10 may be adjusted to improve the operational stability of the semiconductor device 10.

The gate electrode layer 114 has multiple openings OP2 over the array region AR. The extending portions 118b of the source pad 118 extend into the openings OP2. It should be noted that one skilled in the art may adjust the shapes or profiles of the openings OP1, the openings OP2, the extending portions 118a, and the extending portions 118b according to needs, such as circular, square, triangular, hexagonal, octagonal, or irregular shapes with rounded corners. Meanwhile, the openings OP2 in the array region AR may be arranged in a general array, in a staggered array, or in vertical and horizontal line patterns. In addition, the present disclosure does not intend to limit the number, size, and area of the openings OP1, the openings OP1′, the openings OP2, the extending portions 118a, the extending portions 118a′, and the extending portions 118b. One skilled in the art may adjust the aforementioned features according to needs (e.g., to achieve a certain internal resistance of the device), to further improve switching stability.

By forming multiple openings in the gate electrode layer 114 over the peripheral region PR, the area of the gate electrode layer 114 can be reduced, thereby reducing the overlapping area between the gate electrode layer 114 and the first dielectric layer 112. In this way, the parasitic capacitance of the semiconductor device 10 can be reduced, thus improving the switching characteristics, enhancing the forward conduction capability, and increasing the switching stability. In addition, extending the source pad 118 into the openings can increase the source contact area and reduce the source-drain voltage (V_{sd}).

In some embodiments, by disposing the extending portions of the source pad 118 into the openings over the peripheral region PR, the source contact area is increased. As a result, a peripheral portion of the source pad 118 (e.g., portions corresponding to the extending portions 118c shown in FIG. 1 and FIG. 2 and the ring-shaped portion SR shown in FIG. 3) may be omitted.

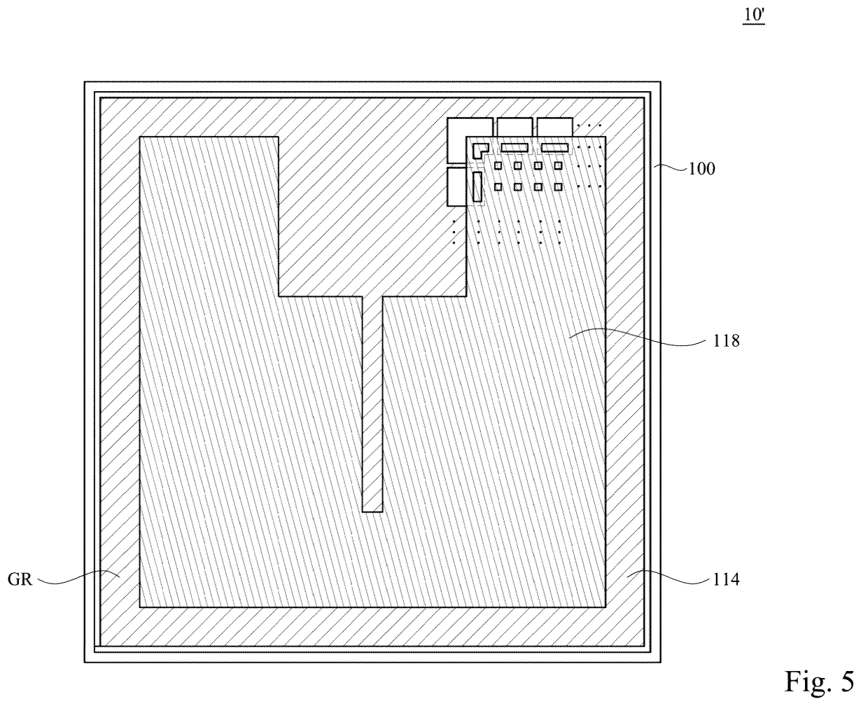

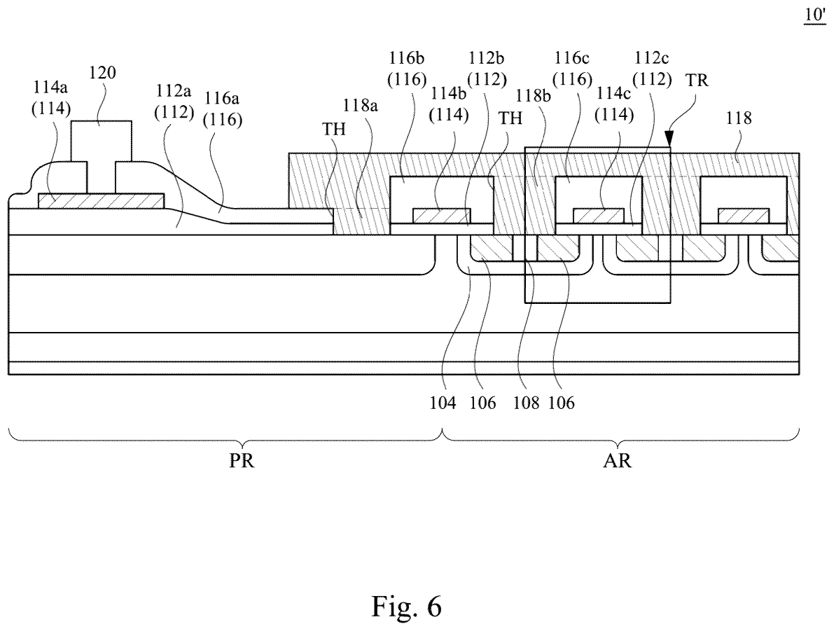

For example, reference is made to FIG. 5 and FIG. 6. FIG. 5 is a top view of a semiconductor device 10′ according to some other embodiments of the present disclosure. FIG. 6 is a partial cross-sectional view of the semiconductor device 10′ corresponding to the line A-A′. As shown, the difference between the semiconductor device 10′ and the semiconductor device 10 is that the semiconductor device 10′ does not have the aforementioned peripheral portion of the source pad 118. To be more specific, as shown in FIG. 5, the semiconductor device 10′ does not have the ring-shaped portion SR of the source pad 118 of the semiconductor device 10. Meanwhile, as shown in FIG. 6, the semiconductor device 10′ does not have the extending portions 118c of the source pad 118 of the semiconductor device 10. In this way, a width of the peripheral region PR can be reduced, so that outer dimensions of the semiconductor device 10′ may be less than outer dimensions of the semiconductor device 10.

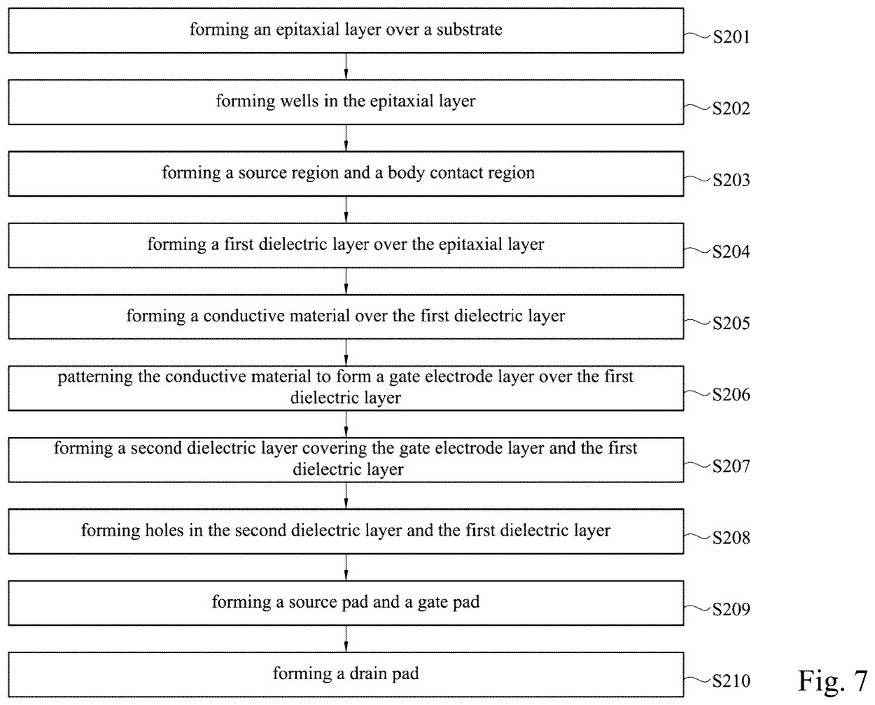

FIG. 7 is a flow chart of a method for forming the semiconductor device 10 according to some embodiments of the present disclosure. As shown in FIG. 7, the method includes steps S201 to S210. Each step of the method will be described accompanied with FIG. 1 and FIG. 4 in subsequent paragraphs.

First, in the step S201, an epitaxial layer 102 is formed over a substrate 100. The substrate 100 includes an array region AR and a peripheral region PR that are adjacent to each other. In some embodiments, the substrate 100 and the epitaxial layer 102 have a first conductivity type (e.g., n-type). In the step S202, a well 104 and a well 110 having a second conductivity type (e.g., p-type) are formed in the epitaxial layer 102. The well 104 and the well 110 are separated from each other. The well 104 is disposed over the array region AR, and the well 110 is disposed over the peripheral region PR. In some embodiments, dopants of the well 110 and dopants of the well 104 are substantially the same and a dopant concentration of the well 110 and a dopant concentration of the well 104 are also substantially the same. In the step S203, a source region 106 and a body contact region 108 are formed in the well 104. In some embodiments, the source region 106 has a first conductivity type (e.g., n-type), and the body contact region 108 has a second conductivity type (e.g., p-type). In some embodiments, the dopants of the well 110 and dopants of the body contact region 108 are substantially the same and the dopant concentration of the well 110 and a dopant concentration of the body contact region 108 are also substantially the same.

Next, in the step S204, a first dielectric layer 112 is formed over the epitaxial layer 102 and over the array region AR and the peripheral region PR. In the step S205, a conductive material is formed over the first dielectric layer 112 and over the array region AR and the peripheral region PR. In the step S206, the conductive material is patterned to form a gate electrode layer 114 over the first dielectric layer 112. In some embodiments, the gate electrode layer 114 is formed such that the gate electrode layer 114 has openings OP1, openings OP1′, and openings OP2 as shown in FIG. 4. In the step S207, a second dielectric layer 116 is formed covering the gate electrode layer 114 and the first dielectric layer 112. In the step S208, holes TH are formed in the second dielectric layer 116 and the first dielectric layer 112. The holes TH are distributed over the peripheral region PR and the array region AR. The holes TH pass through the second dielectric layer 116, the gate electrode layer 114, and the first dielectric layer 112 and partially expose top surfaces of the source region 106, the body contact region 108, and the well 110.

Next, in the step S209, a source pad 118 and a gate pad 120 are formed. To be more specific, the source pad 118 is formed over the gate electrode layer 114 and multiple extending portions (e.g., conductive vias) are formed to fill the holes TH. For example, the extending portions 118a, the extending portions 118b, and the extending portions 118c are formed as shown in FIG. 1. Finally, in the step S210, a drain pad 122 is formed.

Accordingly, in the semiconductor device and the method for forming the semiconductor device of some embodiments of the present disclosure, by forming multiple openings in the gate electrode layer over the peripheral region, the overlapping area between the gate electrode layer and the underlying dielectric layer can be reduced. In this way, the parasitic capacitance of the resultant device can be reduced, thereby improving its switching characteristics, enhancing forward conduction capability, and increasing switching stability. In addition, extending the source pad into the aforementioned openings can increase the source contact area and reduce the source-drain voltage (V_{sd}).

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a substrate comprising an array region and a peripheral region that are adjacent to each other;
an epitaxial layer over the substrate;
a first well in the epitaxial layer;
a dielectric layer over the epitaxial layer and over the array region and the peripheral region;
a gate electrode layer over the dielectric layer and over the array region and the peripheral region, wherein the gate electrode layer has at least one opening over the peripheral region; and
a source pad over the gate electrode layer and extending from over the array region to over the peripheral region, wherein the source pad has at least one first extending portion extending through the at least one opening of the gate electrode layer downward to the first well.

2. The semiconductor device of claim 1, wherein the source pad further has a second extending portion extending downward to the array region.

3. The semiconductor device of claim 1, wherein in a top view, the at least one first extending portion has a rectangular profile.

4. The semiconductor device of claim 1, wherein in a top view, the at least one first extending portion has an L-shaped profile.

5. The semiconductor device of claim 1, wherein a profile of the at least one opening in a top view is rectangular or L-shaped.

6. The semiconductor device of claim 1, wherein the at least one opening of the gate electrode layer comprises a plurality of openings, and the at least one first extending portion of the source pad comprises a plurality of first extending portions, wherein the first extending portions correspond to the openings, and each of the first extending portions extends through its corresponding one of the openings downward to the first well.

7. The semiconductor device of claim 6, wherein the gate electrode layer further comprises a gate line disposed between two adjacent ones of the first extending portions.

8. The semiconductor device of claim 1, wherein the gate electrode layer further comprises a pad region, a ring-shaped portion, a plurality of gate lines, and a plurality of gate electrode portions, wherein the pad region and the ring-shaped portion are connected to each other and disposed over the peripheral region, the gate electrode portions are disposed over the array region, and the gate electrode portions are connected to the pad region and the ring-shaped portion through the gate lines.

9. The semiconductor device of claim 1, further comprises:
a second well in the epitaxial layer and over the array region, wherein the first well and the second well have a first conductivity type; and
a source region in the second well, wherein the source region has a second conductivity type that is different from the first conductivity type.

10. The semiconductor device of claim 9, wherein a dopant concentration of the second well is substantially equal to a dopant concentration of the first well.

11. The semiconductor device of claim 9, wherein a width of the second well is less than a width of the first well.

12. The semiconductor device of claim 9, wherein the first well does not comprise a dopant of the source region.

13. A method for forming a semiconductor device, comprising:
forming an epitaxial layer over a substrate, wherein the substrate comprises an array region and a peripheral region that are adjacent to each other;
forming a first well in the epitaxial layer and over the peripheral region;
forming a first dielectric layer over the epitaxial layer and over the array region and the peripheral region;
forming a gate electrode layer over the first dielectric layer and over the array region and the peripheral region;
forming a hole over the peripheral region, wherein the hole passes through the gate electrode layer and the first dielectric layer and exposes the first well; and
forming a source pad over the gate electrode layer and in contact with the first well through the hole.

14. The method of claim 13, further comprising:
forming a second well in the epitaxial layer and over the array region, wherein the second well and the first well have a first conductivity type; and
forming a source region in the second well, wherein the source region has a second conductivity type that is different from the first conductivity type.

15. The method of claim 14, wherein the second well is formed such that a dopant concentration of the second well is substantially equal to a dopant concentration of the first well.

16. The method of claim 14, wherein the second well is formed such that a width of the second well is less than a width of the first well.

17. The method of claim 14, wherein the first well is formed such that the first well does not comprise a dopant of the source region.
